(19) United States
(12) Patent Application Publication
(10) Pub. No.: US 2019/0006339 A1
(43) Pub. Date: Jan. 3, 2019

(54) THREE-DIMENSIONAL INTEGRATED FAN-OUT WAFER LEVEL PACKAGE

(71) Applicant: ASM Technology Singapore Pte Ltd, Singapore (SG)

(72) Inventors: Hon Shing, John LAU, Palo Alto, CA (US); Ming LI, Hong Kong (HK); Chun Ho FAN, Hong Kong (HK); Teng Hock KUAH, Singapore (SG); Qingqian LI, Hong Kong (HK)

(21) Appl. No.: 15/635,329

(22) Filed: Jun. 28, 2017

(51) Int. Cl. H01L 25/18; H01L 23/31; H01L 23/00; H01L 25/10; H01L 23/367; H01L 21/56; H01L 25/00; H01L 21/683; H01L 21/78

(52) U.S. Cl. CPC H01L 25/18; H01L 25/0652; H01L 24/05; H01L 24/16; H01L 25/105; H01L 24/48; H01L 24/32; H01L 23/3675; H01L 24/03; H01L 21/565; H01L 24/11; H01L 25/50; H01L 24/24; H01L 24/82; H01L 21/6835; H01L 21/78; H01L 24/97; H01L 24/19; H01L 2224/0401; H01L 2224/13024; H01L 2924/1432; H01L 2924/1434; H01L 2924/1431; H01L 2224/04042; H01L 2224/32245; H01L 2224/11334; H01L 2224/24145; H01L 2224/211; H01L 2225/1058; H01L 2225/1023; H01L 2225/06527; H01L 2225/06572; H01L 23/3114

(57) ABSTRACT

An integrated fan-out wafer level package houses a semiconductor package having a first semiconductor die encapsulated by a dielectric compound. A plurality of redistribution layers are formed on a first side of the semiconductor package which are in electrical contact with contact pads of the first semiconductor die. A plurality of solder balls located on the first side of the semiconductor package is electrically connected to the contact pads of the semiconductor die via the redistribution layers. A second semiconductor die is further attached to the first side of the semiconductor package and is electrically connected to the contact pads of the first semiconductor die via the redistribution layers.

### FIELD OF THE INVENTION

The invention relates to the packaging of semiconductor devices, and in particular to fan-out wafer-level packaging.

### BACKGROUND AND PRIOR ART

There are a many approaches to packaging semiconductor devices in the prior art. For high pin-count applications, fan-out wafer-level packaging has become increasingly popular as traditional packaging approaches such as wire bonding and flip-chip bonding reach their limits in terms of electrical connection pitch and cost-effectiveness. Fan-out wafer-level packaging refers to the packaging of an integrated circuit at wafer level, instead of the traditional process of assembling the package of each individual die after the die has been separated from a wafer by cutting. The resulting package is very compact and has a low profile.

An example of a fan-out wafer-level packaging (“FOWLP”) technique is described in U.S. Pat. No. 8,310,051 entitled “Package-on-Package with Fan-out WLCSP”, which describes a package-on-package (“PoP”) including a package carrier, a semiconductor die assembled on the package carrier, and a rewiring laminate structure between the semiconductor die and the package carrier. A plurality of bumps is arranged on the rewiring laminate structure for electrically connecting the semiconductor die with the package carrier. An IC package is also mounted on the package carrier which at least partially overlaps the semiconductor die.

In recent years, PoP technology has been used for housing application processor system-on-chip (“AP SoC”) and mobile dynamic random access memory (“DRAM”) devices for portable electronic products such as smartphones and tablet computers. A typical structure of such a PoP device is illustrated in FIG. 1, which is a cross-sectional view of a PoP package 100 according to the prior art.

The PoP package 100 comprises a bottom package 104 housing an application processor (“AP”) chip 108, and which is mounted on a printed circuit board (“PCB”) 102. The bottom package 104 has been manufactured using an FOWLP technique. As such, the AP chip 108 is mounted on redistribution layers (“RDLs”) 110 which consist of fan-out conductive layers 116 that are embedded in dielectric layers 118. The RDLs 110 at a base of the bottom package 104 are electrically connected to a top portion of the bottom package 104 by through-mold via (“TMV”) 112. The bottom package 104 has a passivation layer 120 on the bottom surface of the RDLs 110 as a protective layer to protect the bottom package 104 from the external environment. Solder balls 124 are placed onto a plurality of solder ball bond pads 122 for mounting and electrically connecting the bottom package 104 to the PCB 102 by way of the solder balls 124. The AP chip 108 and the TMV 112 are encapsulated by epoxy molding compound (“EMC”) 114.

A top package 106 which houses memory chips 130 is in turn mounted on top of the bottom package 104. The memory chips 130 are electrically connected to a coreless package substrate 132 of the top package 106 by wire bonding with wire bonds 134. The memory chips 130 and wire bonds 134 electrically connecting the memory chips 130 to the coreless package substrate 132 are molded with an epoxy molding compound 136. Solder balls 138 are formed on a bottom surface of the coreless package substrate 132 for mounting the top package 106 onto the bottom package 104. For ensuring solder joint reliability of the solder balls 138, an underfill 140 is applied around the solder balls 138 between the bottom and top packages 104, 106.

Electrical communications between the AP chip 108 and the memory chips 130 are thus routed through the RDLs 110 and the TMV 112 of the bottom package 104 to the solder balls 138 connecting the bottom and top packages 104, 106, and also the coreless package substrate 132 and wire bonds 134 of the top package.

In the above format, the top package 106 is used to house memory chips 130 such as mobile DRAM devices. The bottom package 104 is used to house AP chips 108 such as AP SoC.

However, apart from electrical performance, next-generation mobile products increasingly call for ever-thinner package profiles, greater integration flexibility and lower cost. Thus, the current state-of-the-art in PoP technology has room for further improvement to meet these needs. It would be beneficial to further modify the current PoP design by the application of three-dimensional (“3D”) integration to achieve further improvements.

### SUMMARY OF THE INVENTION

It is thus an object of the invention to seek to further lower the semiconductor package profile and cost as compared to the aforementioned prior art.

According to a first aspect of the invention, there is provided an integrated fan-out wafer level package comprising: a semiconductor package comprising a first semiconductor die encapsulated by a dielectric compound; a plurality of redistribution layers formed on a first side of the semiconductor package in electrical contact with contact pads of the first semiconductor die; a plurality of solder balls located on the first side of the semiconductor package and electrically connected to the contact pads of the semiconductor die via the redistribution layers; and a second semiconductor die attached to the first side of the semiconductor package and electrically connected to the contact pads of the first semiconductor die via the redistribution layers.

According to a second aspect of the invention, there is provided a method for fabricating an integrated fan-out wafer level package, the method comprising the steps of: providing a first semiconductor die; forming a plurality of redistribution layers in electrical contact with contact pads of the first semiconductor die; encapsulating the first semiconductor die with a dielectric compound to form a semiconductor package; placing a plurality of solder balls onto the redistribution layers on a first side of the semiconductor package, the solder balls being electrically connected to the contact pads of the semiconductor die via the redistribution layers; and thereafter attaching a second semiconductor die onto the redistribution layers, the second semiconductor die being electrically connected to the contact pads of the first semiconductor die via the redistribution layers.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

Examples of semiconductor packages in accordance with the invention will now be described with reference to the accompanying drawings, in which:

FIG. 1 is a cross-sectional view of a POP package according to the prior art;

FIG. 2 is a cross-sectional view of an FOWLP package in accordance with a first preferred embodiment of the invention;

FIG. 3 is a cross-sectional view of an FOWLP package in accordance with a second preferred embodiment of the invention;

FIG. 4 is a cross-sectional view of the FOWLP package of FIG. 3, including a heat sink attached to the package;

FIGS. 5A to 5C illustrate the formation of contact pads and attachment of die-attach film on a semiconductor die;

FIGS. 6A to 6E illustrate a process for building redistribution layers from the contact pads of application processor chips;

FIG. 7A is a cross-sectional view of singulated application processor packages, FIG. 7B is a cross-sectional view of a memory package which has been wire-bonded to an application processor package and FIG. 7C is a bottom view of an application processor package including a memory chip; and

FIGS. 8A-8C are cross-sectional views of memory packages which have been wire-bonded to application processor packages housing application processor chips from a reconfigured wafer and FIG. 8D is a bottom view of application processor packages including memory chips.

### DETAILED DESCRIPTION OF THE PREFERRED EMBODIMENT OF THE INVENTION

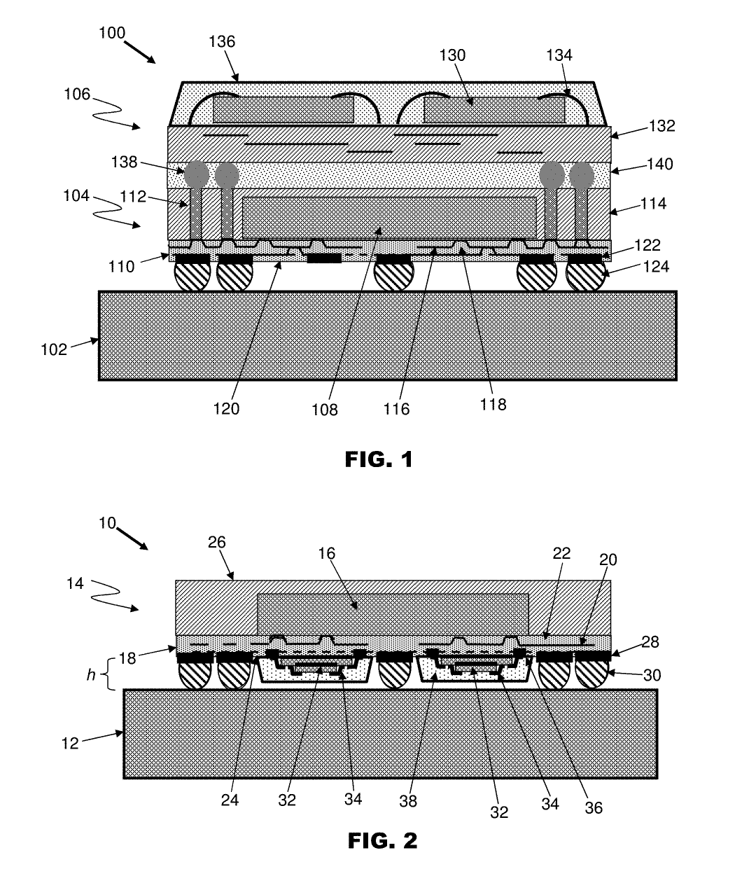

FIG. 2 is a cross-sectional view of an integrated FOWLP package 10 in accordance with a first preferred embodiment of the invention. The FOWLP package 10 is mounted onto a PCB 12, and houses a first semiconductor die, such as an application processor (“AP”) chip 16, as well as a second semiconductor die, such as one or more stacked memory chips 32.

The AP chip 16 is mounted onto a plurality of redistribution layers or RDLs 18 consisting of fan-out conductive layers 20 that are embedded in dielectric layers 22. Contact pads of the AP chip 16 are in electrical contact with the conductive layers 20 of the RDLs 18. The AP chip 16 is embedded or encapsulated in a dielectric compound, which is preferably an epoxy molding compound (“EMC”) 26, to form a semiconductor package such as an application processor (“AP”) package 14. The AP package 14 has a passivation layer 24 on a bottom surface of the RDLs 18. The bottom surface of the AP package 14 also has a plurality of solder ball bond pads 28, on which are placed solder balls 30 which are arranged for electrically mounting the AP package 14 onto the PCB 12. The solder balls 30 are further electrically connected to the contact pads of the AP chip 16 via the RDLs 18.

Additionally, the memory chips 32 are attached to the bottom surface of the AP package 14 and are wire-bonded to the bottom side of the RDLs 18 using wire bonds 34, which connect electrical contacts of the memory chips 32 to wire bond pads 36 located on the RDLs 18. The wire bond pads 36 are in turn electrically connected to the contact pads of the AP chip 16 via the RDLs 18. The memory chips 32 and wire bonds 34 are further protected from the environment by a dielectric encapsulant, such as a glob-top encapsulant 38.

It should be appreciated that in this embodiment, a height of the glob-top encapsulant 38 should be less than a height (h) of the plurality of solder balls 30, to provide sufficient clearance in order to enable the FOWLP package 10 to be successfully mounted onto the PCB 12.

The communications between the AP chip 16 and the memory chips 32 are through the RDLs 18 and the wire bonds 34. Comparing the aforesaid FOWLP package 10 with the PoP package 100 according to the prior art, it would be appreciated that a number of components of the PoP package 100 are eliminated, namely the TMV 112, solder balls 138 connecting the bottom and top packages 104, 106, the underfill 140 and the coreless package substrate 132. The FOWLP package 10 in accordance with the first preferred embodiment of the invention thus leads to a package having a lower profile, better performance and lower cost.

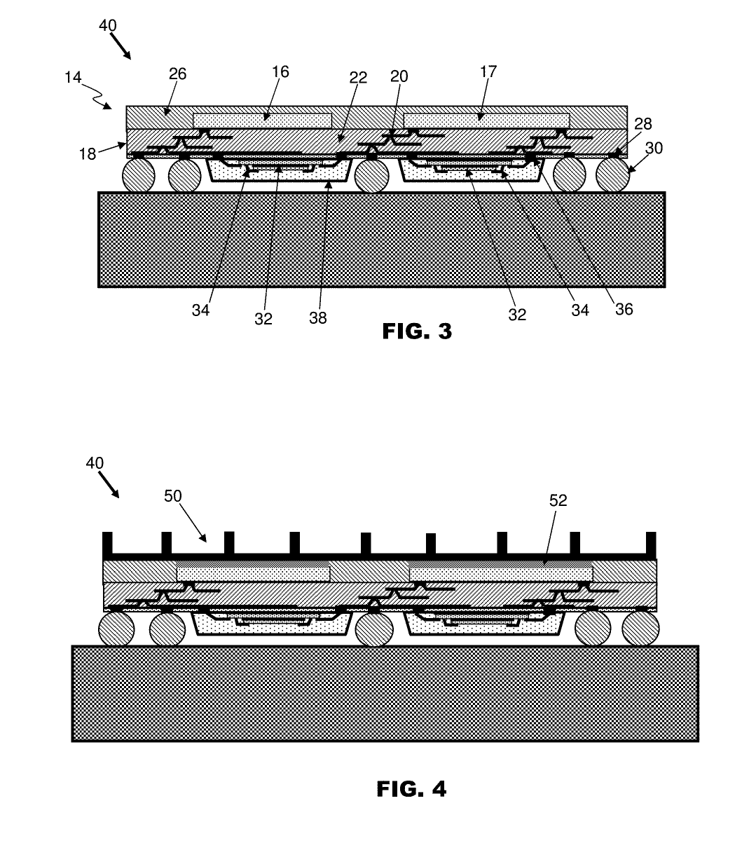

FIG. 3 is a cross-sectional view of an FOWLP package 40 in accordance with a second preferred embodiment of the invention. In this embodiment, there are multiple application processors, such as a first application processor 16 and a third semiconductor die in the form of a second application processor 17, mounted on the RDLs 18. The first and second application processors 16, 17 may comprise logic chips, graphic processor chips, central processing unit processor chips or other semiconductor devices that have been packaged by an FOWLP process. For instance, the first application processor 16 may be a graphics processor chip and the second application processor 17 may be a central processing unit processor chip. The memory chips 32 are attached and wire bonded to a bottom side of the multiple AP (or “MAP”) package 14, as in the first embodiment described above.

The graphics and central processing unit processor chips are both embedded in the same molding compound in the form of an epoxy molding compound (EMC), and the circuitries of the graphics and central processing unit processor chips are fanned out through RDLs 18. The RDLs 18 may have a total thickness of 10-40 μm. The RDLs 18 enable communication between the AP chips 16, 17 and the memory chips 32. The memory chips 32 may be about 35-50 μm thick, and the wire bonds 34 are protected by a glob-top encapsulant 38 with a thickness of about 120 μm. The multiple AP package 14 is attached to a PCB 12 with solder balls 30, the solder balls having a diameter of about 200 μm.

FIG. 4 is a cross-sectional view of the FOWLP package 40 of FIG. 3, including a heat sink 50 attached to the AP package 14 on a second side of the AP package 14 that is opposite to a first side of the AP package 14 which is populated by the solder balls 30. A thermal interface material 52 is first introduced onto a top surface of the multiple AP package 14 next to top surfaces of the first and second AP chips 16, 17. The heat sink 50 or heat spreader is then mounted on top of the thermal interface material 52 to enhance heat dissipation in the FOWLP package 40. Without the presence of the top package 106 found in the prior art, the heat sink 50 is attachable directly next to the AP chips 16, 17 for enhancing heat dissipation. Superior heat dissipation capability helps to reduce any limitations on the allowable sizes of the AP chips 16, 17.

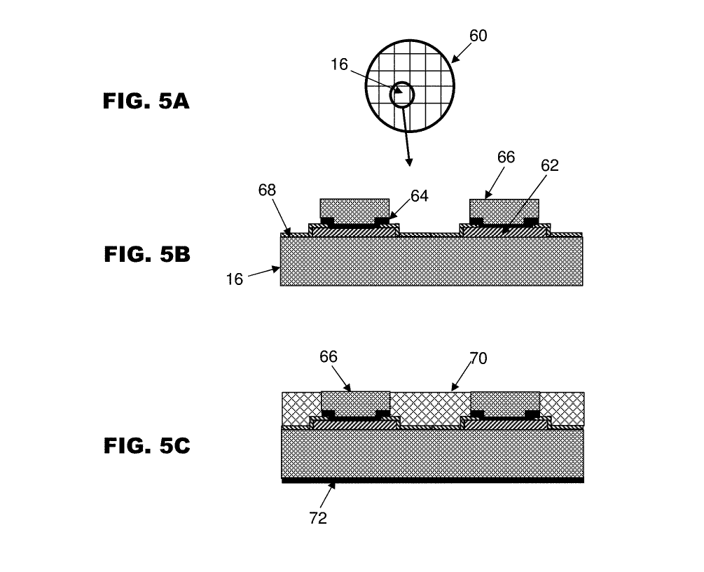

FIGS. 5A to 5C illustrate the formation of contact pads 66 on a semiconductor die or AP chip 16. With reference to FIG. 5A, a device wafer 60 comprises a plurality of AP chips 16. FIG. 5B illustrates one AP chip 16 that is included in the device wafer 60.

The AP chip 16 has a passivation layer 68 and aluminum or copper pads 62 on its top surface. After testing the device wafer 60 for known good dice (or “KGD”), an under bump metallization (“UBM”) layer 64 is formed on the aluminum or copper pads 62, such as by sputtering. Subsequently, copper contact pads 66 are electroplated onto the UBM layer 64 to complete the electrical contacts. In FIG. 5C, a spin coating process has deposited a polymer material 70 on top of the AP chips 16 of the device wafer 60, leaving only the copper contact pads 66 exposed. Finally, a bottom surface of the device wafer 60 is laminated with a die-attach film (“DAF”) 72 of about 20-25 μm thick, before the individual AP chips 16 are divided into separated AP chips 16 or packages in a later dicing process.

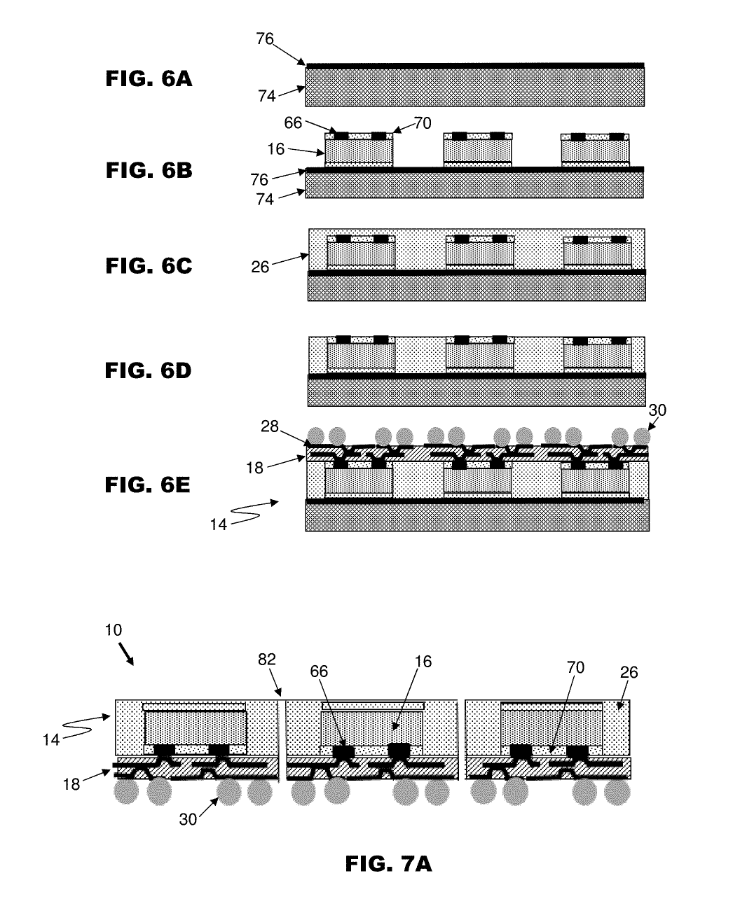

FIGS. 6A to 6E illustrate an FOWLP assembly process for building RDLs 18 on contact pads of an AP chip 16 in order to form an AP package 14, such as that illustrated in FIG. 2. In FIG. 6A, a light-to-heat conversion (“LTHC”) release layer 76 is formed on top of a temporary carrier, such as a glass carrier 74, for example by spin coating. The glass carrier 74 may have a thermal expansion coefficient of 8×10⁻⁶/° C., and a thickness of about 1 mm.

In FIG. 6B, AP chips 16 that have been confirmed to be KGD are individually picked and placed face-up on the LTHC layer 76 of the glass carrier 74. Then, the DAF 72 is cured at about 150° C. for approximately one hour. It should be appreciated that the temporary carrier may be in the form of a reconstituted carrier or a reconfigured carrier. The reconstituted carrier comprising the glass carrier 74 having the LTHC layer 76, and the AP chips 16 comprising the copper contact pads 66, the DAF 72 and the polymer layer 70 are then molded with epoxy molding compound, as shown in FIG. 6C. Such molding may be performed by compression molding, as known in the art.

In FIG. 6D, excess epoxy molding compound 26 and polymer layer 70 are removed by back-grinding so as to expose the copper contact pads 66. The RDLs 18 are thereafter formed to create fan-out electrical connections with the copper contact pads 66, as shown in FIG. 6E. Solder balls 30 are then mounted onto the solder ball bond pads 28 located on the surface of the RDLs 18.

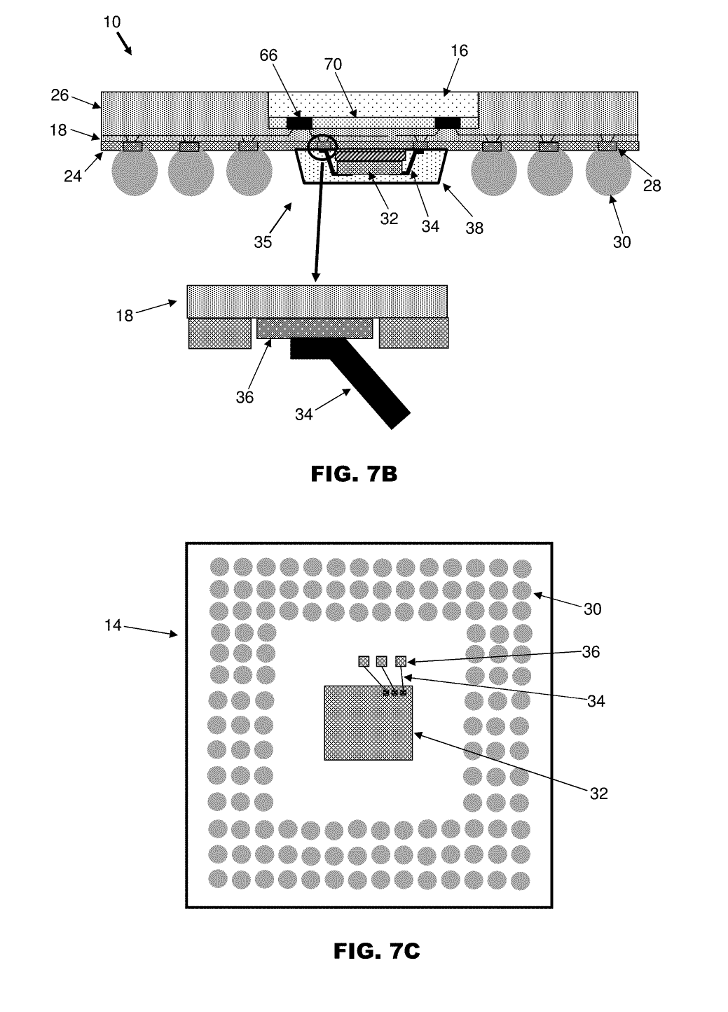

FIG. 7A is a cross-sectional view of a plurality of singulated AP packages 14 according to a first approach of attaching a memory package according to the invention. From the AP packages 14 shown in FIG. 6E, the glass carrier 74 has been removed and the AP packages 14 have been diced and separated to produce the singulated AP packages 14.

FIG. 7B is a cross-sectional view of a memory package 35 which has been wire-bonded to an individual AP package 14 which has been singulated after collective formation of a plurality of AP packages 14 from the reconstituted wafer. A memory chip 32 is attached to a bottom surface of a separated AP package 14, such as by way of die-attach film positioned between the memory chip 32 and the separated AP package 14. After curing to solidify the bond of the memory chip 32 onto the AP package 14, wire bonding is performed between contact pads on the memory chip 32 and wire bond pads 36 on the RDL 18 to form wire bonds 34. The memory chip 32 and wire bonds 34 are encapsulated by glob-topping them with a glob-top encapsulant 38, and the glob-top encapsulant 38 is cured thereafter.

FIG. 7C is a bottom view of the singulated AP package on which a memory chip 32 has been bonded, but before protecting the memory chip 32 and wire bonds by encapsulating them with a glob-top encapsulant 38. It illustrates the wire bonds 34 made between the memory chip 32 and the wire bond pads 36.

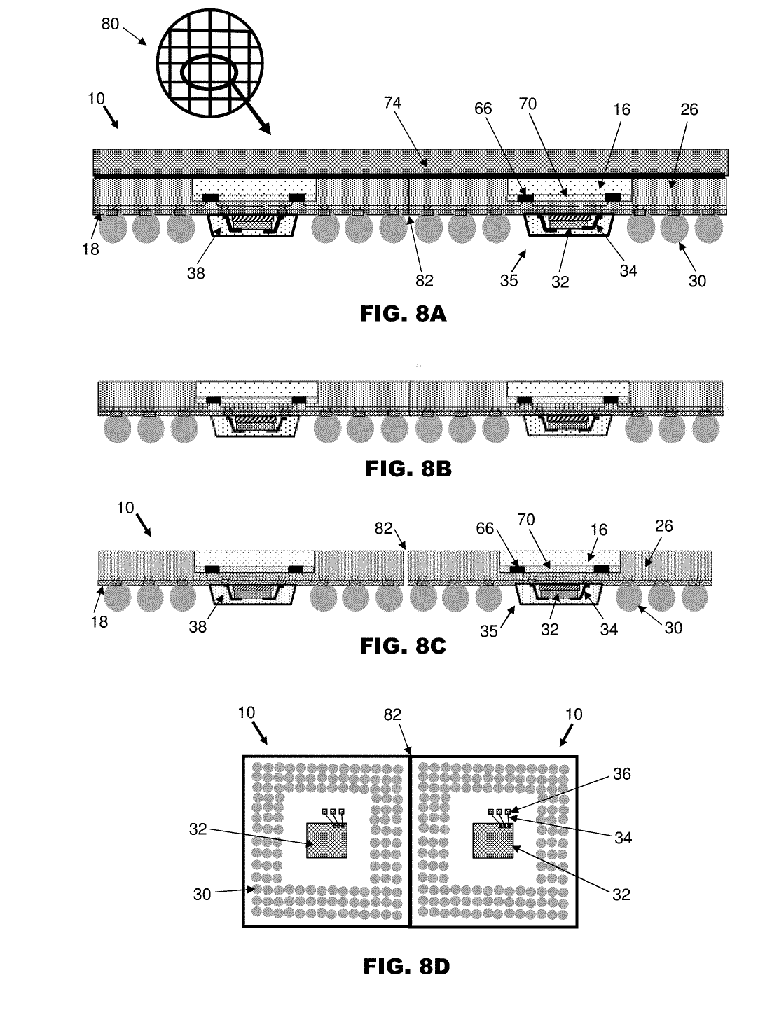

FIGS. 8A-8C are cross-sectional views of memory packages 35 which have been wire-bonded to AP packages 14 housing AP chips 16 from a reconfigured wafer. This approach is different from the approach illustrated in FIG. 7A and FIG. 7B in that memory chips 32 are attached to a bottom surface of the plurality of AP packages 14 before they are separated.

In FIG. 8A, while the AP packages 14 are still supported by the glass carrier 74, the memory chips 32 are attached to the AP packages 14 via die-attach film and are cured to solidify the attachment of the memory chips 32 to the AP packages 14. Thereafter, wire bonding is performed between contact pads on the memory chips 32 and wire bond pads on the RDL 18 to form wire bonds 34. The memory chips 32 and wire bonds 34 are then encapsulated by glob-topping them with a glob-top encapsulant 38. Thereafter, the glob-top encapsulant 38 is cured. The glass carrier 74 would be removed before the AP packages 14 are singulated.

On the other hand, in the approach illustrated in FIG. 8B, the glass carrier 74 is first removed before the memory chips 32 are attached to the AP packages via die-attach film and cured. Wire bonding is then performed between contact pads on the memory chips 32 and wire bond pads on the RDL 18 to form wire bonds 34. The memory chips 32 and wire bonds 34 are subsequently encapsulated by glob-topping them with a glob-top encapsulant 38. Thereafter, the glob-top encapsulant 38 is cured.

In both the approaches illustrated and FIGS. 8A and 8B, the formed FOWLP packages 10 are connected to each other, but they are subsequently singulated into individual FOWLP packages 10 along separation lines 82. FIG, 8C are cross-sectional views of FOWLP packages 10 that have been singulated along a separation line 82.

FIG. 8D is a bottom view of AP packages 14 on which memory chips 32 have been bonded, but before protecting the memory chips 32 and wire bonds 34 by encapsulating them with a glob-top encapsulant 38. It illustrates the wire bonds 34 made between the respective memory chips 32 and the wire bond pads 36, prior to separation of the connected FOWLP packages 10 by dicing along the separation line 82.

It would be appreciated that, in order to lower the package profile and cost, the need for two separate bottom and top packages 104, 106 for housing the AP chip 108, such as a flip chip AP SoC and a memory chip 130 such as a mobile DRAM, have been replaced by a single fan-out wafer-level AP package 14. As such, a coreless substrate, solder ball attachment, fluxing, flip chip assembly, cleaning, underfill dispensing and curing, TMV and the building-up of an organic package substrate are eliminated. This leads to a lower profile and lower-cost PoP device.

The invention described herein is susceptible to variations, modifications and/or additions other than those specifically described and it is to be understood that the invention includes all such variations, modifications and/or additions which fall within the spirit and scope of the above description.

1. An integrated fan-out wafer level package comprising:
a semiconductor package comprising a first semiconductor die encapsulated by a dielectric compound;
a plurality of redistribution layers formed on a first side of the semiconductor package in electrical contact with contact pads of the first semiconductor die;
a plurality of solder balls located on the first side of the semiconductor package and electrically connected to the contact pads of the semiconductor die via the redistribution layers; and
a second semiconductor die attached to the first side of the semiconductor package and electrically connected to the contact pads of the first semiconductor die via the redistribution layers; and
a plurality of wire bond pads formed on the redistribution layers on the first side of the semiconductor package and wire bonds directly connecting the second semiconductor die to the wire bond pads.

2. The integrated fan-out wafer level package as claimed in claim 1, wherein the plurality of solder balls is arranged for electrically mounting the integrated fan-out wafer level package onto a printed circuit board.

3. The integrated fan-out wafer level package as claimed in claim 1, wherein the first semiconductor die comprises an application processor chip.

4. The integrated fan-out wafer level package as claimed in claim 3, wherein the application processor is selected from the group consisting of:
logic chip, graphics processor chip and central processing unit processor chip.

5. The integrated fan-out wafer level package as claimed in claim 3, wherein the second semiconductor die comprises one or more memory chips.

6. (canceled)

7. The integrated fan-out wafer level package as claimed in claim 1, further comprising a dielectric encapsulant for encapsulating and protecting the second semiconductor chip and the wire bonds from the environment.

8. The integrated fan-out wafer level package as claimed in claim 7, wherein the dielectric encapsulant comprises a glob-top encapsulant.

9. The integrated fan-out wafer level package as claimed in claim 7, wherein a height of the dielectric encapsulant is less than a height of the plurality of solder balls.

10. The integrated fan-out wafer level package as claimed in claim 1, further comprising a third semiconductor die, wherein the first and third semiconductor dice are both encapsulated by the same dielectric compound.

11. The integrated fan-out wafer level package as claimed in claim 1, further comprising a heat sink attached on a second side of the semiconductor package next to the first semiconductor die, the second side being opposite to the first side of the semiconductor package.

12. The integrated fan-out wafer level package as claimed in claim 11, further comprising a thermal interface material present between the heat sink and a surface of the first semiconductor die.

13. A method for fabricating an integrated fan-out wafer level package, the method comprising the steps of:
providing a first semiconductor die;
forming a plurality of redistribution layers in electrical contact with contact pads of the first semiconductor die;
encapsulating the first semiconductor die with a dielectric compound to form a semiconductor package;
placing a plurality of solder balls onto the redistribution layers on a first side of the semiconductor package, the solder balls being electrically connected to the contact pads of the semiconductor die via the redistribution layers;
attaching a second semiconductor die onto the redistribution layers; and thereafter directly wire bonding the second semiconductor die to a plurality of wire bond pads formed on the redistribution layers with wire bonds on the first side of the semiconductor package, so that the second semiconductor die is electrically connected to the contact pads of the first semiconductor die via the redistribution layers.

14. The method as claimed in claim 13, wherein the step of providing the first semiconductor die comprises the step of mounting a plurality of the first semiconductor die onto a carrier.

15. The method as claimed in claim 14, further comprising the steps of removing the carrier and singulating and separating the plurality of the first semiconductor die from one another, prior to attaching the second semiconductor die onto the redistribution layers.

16. (canceled)

17. The method as claimed in claim 14, further comprising the step of glob-topping the second semiconductor die and wire bonds with a dielectric encapsulant.

18. The method as claimed in claim 14, wherein the second semiconductor die is attached when the plurality of the first semiconductor die is still mounted onto the carrier and before the carrier is removed.

19. The method as claimed in claim 18, further comprising the steps of removing the carrier and singulating the plurality of the first semiconductor die from one another, after attaching the second semiconductor die onto the redistribution layers.

20. The method as claimed in claim 14, wherein the carrier is removed before attaching the second semiconductor die onto the redistribution layers, and further comprising the step of singulating the plurality of the first semiconductor die from one another after attaching the second semiconductor die.
